(19) United States
(12) Patent Application Publication
(10) Pub. No.: US 2008/0122026 A1
(43) Pub. Date: May 29, 2008

(54) STRUCTURE FOR CREATION OF A PROGRAMMABLE DEVICE

(75) Inventors: Xiangdong Chen, Poughquag, NY (US); Deok-Kee Kim, Bedford Hills, NY (US); Haining Yang, Wappingers Falls, NY (US)

Correspondence Address: INTERNATIONAL BUSINESS MACHINES CORPORATION;DEPT. 18G, BLDG. 300-482, 2070 ROUTE 52, HOPEWELL JUNCTION, NY, 12533, US

(73) Assignee: INTERNATIONAL BUSINESS MACHINES CORPORATION, Armonk, NY (US)

(21) Appl. No.: 11/564,344

(22) Filed: Nov. 29, 2006

(51) Int. Cl. H01L 29/00

(52) U.S. Cl. 257/529; 257/E23.147

(57) ABSTRACT

The invention is directed to an improved eFUSE that prevent rupturing of the fuse link, reduces current through the fuse link, and optimizes electromigration through the fuse link through the use of a feedback circuit.

### BACKGROUND OF THE INVENTION

1. Field of the Invention

The invention relates generally to semiconductor devices, and more particularly to a programmable semiconductor device.

2. Description of the Related Art

eFUSE, which is an electrically programmable fuse, is an important semiconductor technology. An eFUSE enables a semiconductor device to self-repair. More specifically, the eFUSE enables a semiconductor device to reroute circuit operations to another location on the semiconductor device, if a location in the semiconductor device is not working properly. Such self-repair improves yield for the semiconductor device.

FIG. 1 depicts a prior art semiconductor device 100. More particularly, FIG. 1 depicts a prior art eFUSE. The features characteristic of a prior art eFUSE include a semiconductor 110 with two ends 112a, 112b separated by a fuse link 114 and connected to the source or drain 122 of a transistor 120 at the wider of the two ends 112b. The transistor 120 is known as a programming transistor. The wider end 112b of the transistor 120 is known as the cathode, the narrower end 112a of the transistor 120 is known as the anode, and the fuse link 114 is known as the resistor.

The prior art eFUSE of FIG. 1 suffers the disadvantage of only tow conditions, namely high and low resistance. While a constant current flows through the resistor 114, the voltage at the cathode 120 varies. The narrow width of the resistor 114 causes high resistance. Such high resistance causes rupturing of the resistor 114, which in turn causes reliability concerns in the semiconductor device 100.

FIG. 2 depicts the electrical characteristics of the prior art semiconductor device 100 of FIG. 1. As shown, the semiconductor device 100 comprises only the two conditions of high and low resistance, 234 and 232 respectively. The current 242 through the resistor 114 remains the same. The varying cathode voltage 112b is depicted. Note that the cathode voltage has two voltages, 264 and 262 respectively.

What is needed in the art is an improved a eFUSE that prevents rupturing of the resistor 114, reduces current through the resistor 114, and optimizes electromigration through the resistor 114.

### BRIEF SUMMARY OF THE INVENTION

The invention is directed to an improved eFUSE.

A first embodiment is directed to a programmable device. The programmable device comprises a semiconductor material, a first transistor, and a feedback circuit. The semiconductor material is on an insulator that is on a substrate. The semiconductor material has a first and second end and a fuse link between the fist and second ends. The first transistor has a drain or source connected to the first of second ends and the other drain or source connected to a substantially zero voltage source. The feedback circuit is connected to the first or second end and prevents rupturing of the fuse link, reduces current through the fuse link and/or optimizes electromigration through the fuse link.

The invention solves the aforementioned problems associated with prior art eFUSE. More specifically, the invention includes a feedback circuit which accomplishes at least one, if not all of the following: prevents rupturing of the fuse link, reduces current through the fuse link, and optimizes electromigration through the fuse link.

For at least the foregoing reasons, the invention improves a eFUSE technology.

### BRIEF DESCRIPTION OF THE DRAWINGS

The features and the element characteristics of the invention are set forth with particularity in the appended claims. The figures are for illustrative purposes only and are not drawn to scale. Furthermore, like numbers represent like features in the drawings. The invention itself, however, both as to organization and method of operation, may best be understood by reference to the detailed description which follows, taken in conjunction with the accompanying figures, in which:

FIG. 1 depicts a prior art semiconductor device 100;

FIG. 2 depicts the electrical characteristics of the prior art semiconductor device 100 of FIG. 1;

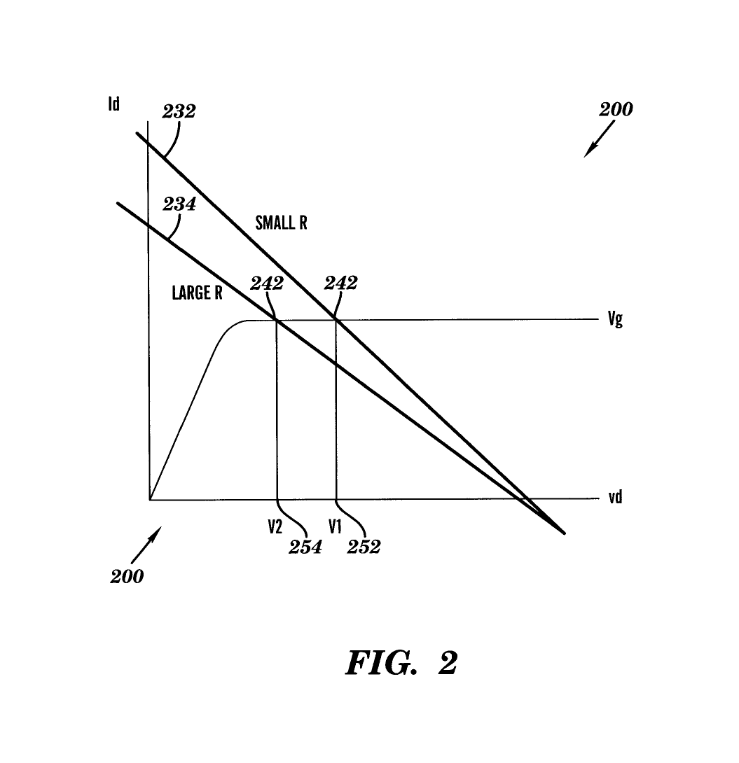

FIG. 3 depicts an embodiment of the invention; and,

FIG. 4 depicts the electrical characteristics of the circuit of FIG. 3.

### DETAILED DESCRIPTION OF THE INVENTION

The invention will now be described with reference to the accompanying figures. In the figures, various aspects of the structures have been depicted and schematically repressed in a simplified manner to more clearly describe and illustrate the invention.

By way of overview and introduction, the invention is directed to an improved eFUSE with a feedback circuit that prevents rupturing of the resistor, reduces current through the resistor, and/or optimizes electromigration through the resistor. In turn, such improved eFUSE is advantageous because the eFUSE is more robust to process variation. The resistance of the resistor varies due to process control. In the prior art, the same current flows through the resistor no matter the resistance through the resistor. Therefore, with the prior art, for a narrow width resistor, the temperature of the resistor increases significantly, which causes the resistor to rupture, which in turn deteriorates circuit yield, by contrast, the invention adjust the current through the resistor. Therefore, the invention prevents resistor rupture, which improves circuit yield.

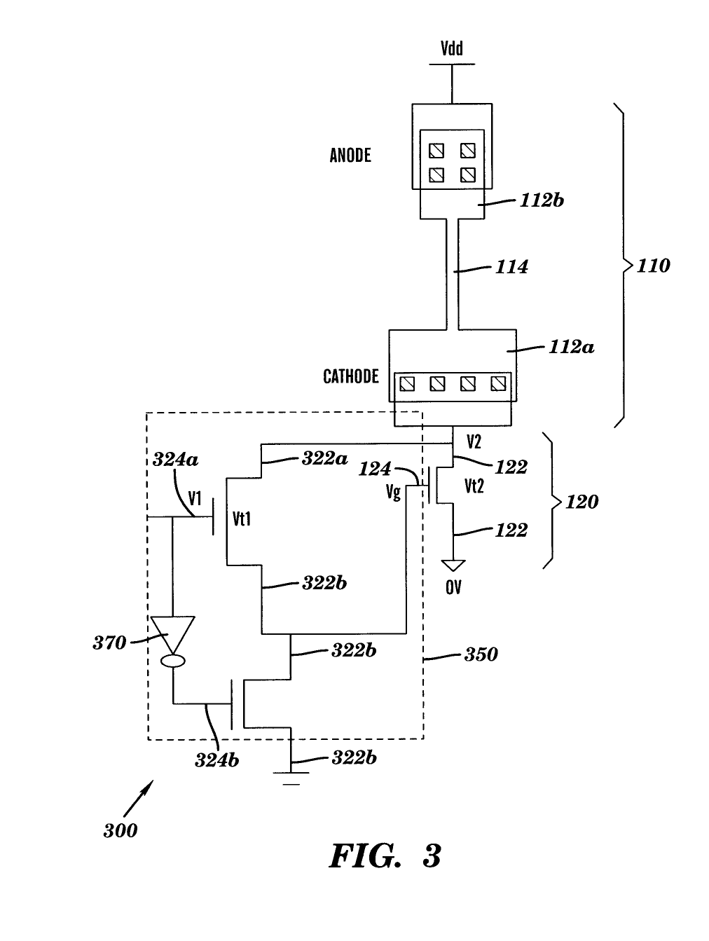

An embodiment of the invention 300 will be described with reference to the FIG. 3. The embodiment 300 includes a semiconductor material 110, transistor 120, and a feedback circuit 350. The semiconductor material 110 includes two ends 112a, 112b separated by a fuse link 114. The transistor 120 includes a source or drain 122 connected to the wider of the two ends 112a of the semiconductor material 110 and source or drain that is not already connected to the wider of the two ends 112a connected to a substantially zero voltage source, such as ground. The feedback circuit 350 is connected to the wider end 112a of the semiconductor material 110. The feedback circuit accomplishes at least, if not all, of the following: prevents rupturing of the fuse link 114, reduces current through the fuse link 114, and optimizes electromigration through the fuse link 114.

The feedback circuit 350 of FIG. 3 includes two additional transistors 320a, 320b and an inverter 370. One of the additional transistors 320a has either a drain or source 322a connected to the wider end 112a of the semiconductor material 110 and the gate 324a connected to the input of the inverter 370. Such transistor 320a is known as a pass transistor. The other transistor 320b has a gate 324b connected to the output of the inverter 370, either a drain or source 322b connected to the other of the drain or source of transistor 320a, and the other of the source of drain 322b connected to a substantially zero voltage source, such as ground. Such transistor 320b is known as pull off or blow out transistor. Often the pull off transistor 320b is a NMOSFET.

The transistors 120, 320a320b of FIG. 3 are either “on” or “off.” Whenever the pass transistor 320a is “on,” the pull off transistor 320b “off, ” and the programming transistor 120 is also “on.” On the contrary, whenever the pass transistor 320a is “off,” the pull off transistor 320b is “on”, and the programming transistor 120 is also “off.”

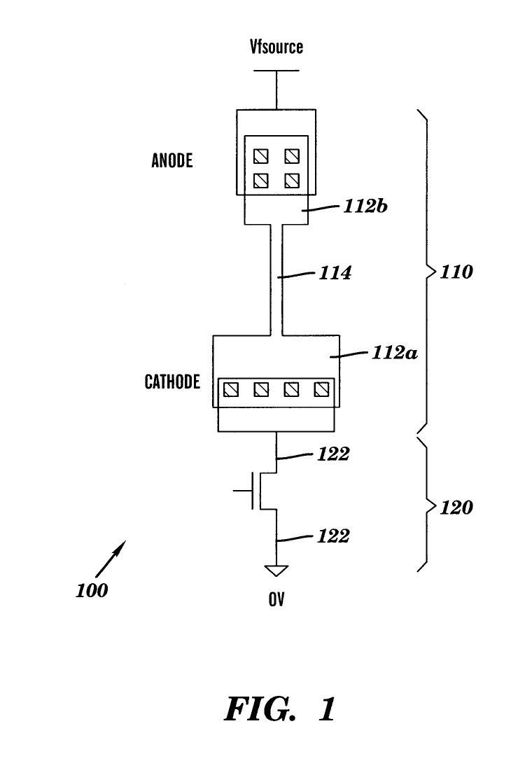

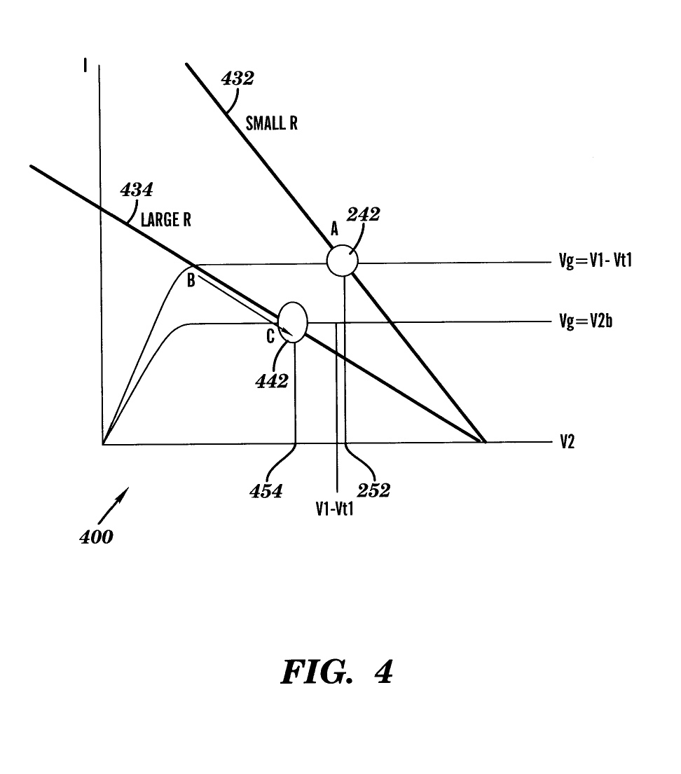

FIG. 4 depicts the electrical characteristics of the circuit of FIG. 3. Note that when the resistance through the fuse link 114 is low 432, the circuit of FIG. 3 behaving as the prior art circuit of FIG. 1, namely the current through the fuse link 114 remains constant. In this state, the programming transistor 120 is “on,” the pull off transistor 320b is off, and the pass transistor 320a is “on,” the pull off resistance through the fuse link 114 is high 434, the circuit of FIG. 3 behaves differently than the prior art circuit of FIG. 1. More specifically, when the resistance through the fuse link 114 is high 434, the current through the fuse link 114 reduces, which prevents rupture of the fuse link 114. In this state, the programming transistor 120 is “off,” the pull off transistor 320b is off, and the pass transistor 320a is “on.”

Unlike the prior art depicted in FIG. 1, the embodiment depicted in FIG. 3 prevents rupturing of the fuse link 114, which in turn improves circuit yield.

The invention solves the aforementioned problems associated with a prior art eFUSE. More specifically, the invention prevents rupturing of the fuse link, reduces current through the fuse link, and optimizes electromigration through the fuse link.

While the invention has been particularly described in conjunction with a specific preferred embodiment and other alternative embodiments, it is evident that numerous alternatives, modifications and variations will be apparent to those skilled in the art in light of the foregoing description. It is therefore intended that the appended claims embrace all such alternatives, modifications and variations as falling within the true scope and spirit of the invention.

What is claimed is:

1. A programmable device, comprising:
a semiconductor material on an insulator that is on substrate, the semiconductor material having a first and second end and fuse link between the first and second ends;
a first transistor with (1) one of drain and source connected to one of the first and second ends and (2) other of the one of drain and source connected to a first substantially zero voltage source;
a feedback circuit connected to one of the first and second ends that at least one of prevents rupturing of the fuse link, reduces current through the fuse link, and optimizes electromigration through the fuse link.

2. A device as claimed in claim 1, the substrate comprising one of Si and SOI.

3. A device as claimed in claim 1, the insulator comprising one of silicon oxide, oxynitride, HfO₂, and ArO₂.

4. A device as claimed in claim 1, the semiconductor material comprising polysilicon.

5. A device as claimed in claim 1, the feedback circuit reduces current through the fuse link when resistance through the fuse link is one of substantially equal to and greater than 20.0% of a previous resistance through the fuse link.

6. A device as claimed in claim 1, the feedback circuit comprising,
a second transistor with one of drain and source connected to one of the first and second ends;
an inverter with input connected to gate of the second transistor; and,
a third transistor with (1) one of drain and source connected to other of the one of drain and source of the second transistor, (2) gate connected to output of the inverter, and (2) other of the one drain and source connected to a second substantially zero voltage source.

7. A device as claimed in claim 1, the first end wider than the second end.

8. A device as claimed in 7, the one of drain and source of the first transistor connected to the first end.

9. A device as claimed in claim 1, the substantially zero voltage source is ground.

10. A device as claimed in claim 1, the first transistor comprises a programming transistor.

11. A device as claimed in claim 6, the first end wider than the second end.

12. A device as claimed in claim 11, the one of drain and source of the first transistor connected to the first end.

13. A device as claimed in claim 11, the one of drain and source of the second transistor connected to the first end.

14. A device as claimed in claim 6, the second substantially zero voltage source is ground.

15. A device as claimed in claim 6, the first transistor comprising a programming transistor.

16. A device as claimed in 15, the programming transistor creating an open circuit fuse link.

17. A device as claimed in claim 6, the second transistor comprising a pass transistor.

18. A device as claimed in claim 6, the third transistor comprising a pull off transistor.

19. A device as claimed in claim 18, the third transistor comprising a NMOSFET transistor.

20. A device as claimed in claim 18, the third transistor causing gate voltage of the first transistor to be substantially zero when the second transistor is off.
